(19) United States
(12) Patent Application Publication
(10) Pub. No.: US 2009/0101987 A1
(43) Pub. Date: Apr. 23, 2009

(54) SEMICONDUCTOR DEVICE AND METHOD FOR MANUFACTURING SAME

(75) Inventors: Kaoru HIYAMA, Kanagawa-ken (JP); Tatsurou Sawada, Kanagawa-ken (JP); Osamu Fujii, Kanagawa-ken (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 12/252,140

(22) Filed: Oct. 15, 2008

(30) Foreign Application Priority Data
Oct. 16, 2007 (JP) 2007-269039

(51) Int. Cl. H01L 27/092; H01L 21/311

(52) U.S. Cl. 257/369; 438/694; 257/E27.062; 257/E21.249

(57) ABSTRACT

A semiconductor device includes: a semiconductor substrate; a p-channel field effect transistor formed in a first region of the semiconductor substrate; an n-channel field effect transistor formed in a second region of the semiconductor substrate; a compressive stress film with a compressive stress generated inside, the compressive stress film covering the first region; a tensile stress film with a tensile stress generated inside, the tensile stress film covering the second region; and a buffer film located between the p-channel field effect transistor and the n-channel field effect transistor on the semiconductor substrate, the magnitude of internal stress of the buffer film being smaller than the magnitude of the compressive stress of the compressive stress film and the magnitude of the tensile stress of the tensile stress film.

### CROSS-REFERENCE TO RELATED APPLICATIONS

This application is based upon and claims the benefit of priority from the prior Japanese Patent Application No. 2007-269039, filed on Oct. 16, 2007; the entire contents of which are incorporated herein by reference.

### BACKGROUND OF THE INVENTION

1. Field of the Invention

This invention relates to a semiconductor device and a method for manufacturing the same, and more particularly to a semiconductor device including both p-channel and n-channel field effect transistors and a method for manufacturing the same.

2. Background Art

Semiconductor devices including both a p-channel field effect transistor (p-MOSFET (metal oxide semiconductor field effect transistor), hereinafter referred to as “pMOS”) and an n-channel field effect transistor (n-MOSFET, hereinafter referred to as “nMOS”) are widely used. Recently, it has been known that the driving performance of a pMOS is enhanced by compressing the channel region of the pMOS, that is, making the lattice spacing of the channel region smaller than the original lattice constant, and that the driving performance of an nMOS is enhanced by expanding the channel region of the nMOS, that is, making the lattice spacing of the channel region larger than the original lattice constant.

In this context, the technique of using film stress to enhance the driving performance of a transistor, that is, the DSL (dual stress liner) technique, is developed. For example, for the purpose of enhancing the driving performance of both pMOS and nMOS, JP-A-2005-057301(Kokai) discloses a technique of forming in the pMOS region a film for compressing the channel region directly below the gate electrode by pushing outward the region between the gate electrodes in the direction of separating the gate electrodes from each other, and forming in the nMOS region a film for expanding the channel region directly below the gate electrode by pulling the gate electrodes In the direction of coming close to each other.

However, in such a semiconductor device, the pMOS and nMOS are often located close to each other, such as in the case of forming a CMOS (complementary metal oxide semiconductor). In such cases, in the vicinity of the boundary between the PMOS region and the nMOS region, the compressive force applied to the substrate by the film located in the pMOS region and the expansive force applied to the substrate by the film located in the nMOS region cancel out each other, This causes a problem in that the transistor located in the vicinity of the boundary has lower driving performance than the transistor located away from the boundary. If some transistors have lower driving performance than other transistors as described above, the circuit operation may encounter trouble. This problem becomes more serious with the downscaling of semiconductor devices in which the distance between the pMOS region and the nMOS region is decreased. Conversely, to ensure a certain driving performance for all the transistors, the pMOS region and the nMOS region need to be spaced to some extent, which interferes with the downsizing of the semiconductor device.

### SUMMARY OF THE INVENTION

According to an aspect of the invention, there is provided a semiconductor device including; a semiconductor substrate; a p-channel field effect transistor formed in a first region of the semiconductor substrate; an n-channel field effect transistor formed in a second region of the semiconductor substrate; a compressive stress film with a compressive stress generated inside, the compressive stress film covering the first region; a tensile stress film with a tensile stress generated inside, the tensile stress film covering the second region; and a buffer film located between the p-channel field effect transistor and the n-channel field effect transistor on the semiconductor substrate, the magnitude of internal stress of the buffer film being smaller than the magnitude of the compressive stress of the compressive stress film and the magnitude of the tensile stress of the tensile stress film.

According to another aspect of the invention, there is provided A method for manufacturing a semiconductor device, including: forming a p-channel field effect transistor in a first region of a semiconductor substrate and forming an n-channel field effect transistor in a second region of the semiconductor substrate; forming a compressive stress film with a compressive stress generated inside so that the compressive stress film covers the first region; forming a buffer film entirely, the magnitude of internal stress of the buffer film being smaller than the magnitude of the compressive stress of the compressive stress film; etching the buffer film so that the buffer film is left at least on an end side surface of the compressive stress film on the second region side; entirely forming a tensile stress film with a tensile stress generated inside, the magnitude of the tensile stress being larger than the magnitude of the internal stress of the buffer film; and selectively removing the tensile stress film so that the tensile stress film is left on the second region, on an end portion of the compressive stress film on the second region side, and on the buffer film.

According to still another aspect of the invention, there is provided A method for manufacturing a semiconductor device, including: forming a p-channel field effect transistor in a first region of a semiconductor substrate and forming an n-channel field effect transistor in a second region of the semiconductor substrate; forming a tensile stress film with a tensile stress generated inside so that the tensile stress film covers the second region; forming a buffer film entirely, the magnitude of internal stress of the buffer film being smaller than the magnitude of the tensile stress of the tensile stress film; etching the buffer film so that the buffer film is left at least on an end side surface of the tensile stress film on the first region side; entirely forming a compressive stress film with a compressive stress generated inside, the magnitude of the compressive stress being larger than the magnitude of the internal stress of the buffer film; and selectively removing the compressive stress film so that the compressive stress film is left on the first region, on an end portion of the tensile stress film on the first region side, and on the buffer film.

### BRIEF DESCRIPTION OF THE DRAWINGS

FIG. 1 is a plan view illustrating a semiconductor device according to a first embodiment of the invention;

FIG. 2 is a cross-sectional view taken along line A-A″ shown in FIG. 1;

FIG. 3 is a cross-sectional view illustrating the operation of the semiconductor device according to the first embodiment;

FIGS. 4A to 4E are process cross-sectional views illustrating the method for manufacturing a semiconductor device according to the first embodiment;

FIG. 5A is a process cross-sectional view illustrating a method for manufacturing a semiconductor device according to a first variation of the first embodiment, and FIG. 5B is a cross-sectional view illustrating this semiconductor device;

FIG. 6A is a process cross-sectional view illustrating a method for manufacturing a semiconductor device according to a second variation of the first embodiment, FIG. 6B is a cross-sectional view illustrating this semiconductor device, and FIG. 6C is a process cross-sectional view illustrating another method for manufacturing a semiconductor device according to this variation;

FIG. 7A is a process cross-sectional view illustrating a method for manufacturing a semiconductor device according to a second embodiment of the invention, and FIG. 7B is a cross-sectional view illustrating the semiconductor device according to this embodiment;

FIG. 8A is a process cross-sectional view illustrating another method for manufacturing a semiconductor device according to the second embodiment, and FIG. 8B is a process cross-sectional view illustrating still another method for manufacturing a semiconductor device according to this embodiment; and

FIG. 9 is a cross-sectional view illustrating a semiconductor device according to a third embodiment of the Invention.

### DETAILED DESCRIPTION OF THE INVENTION

Embodiments of the invention will now be described with reference to the drawings, beginning with a first embodiment of the invention.

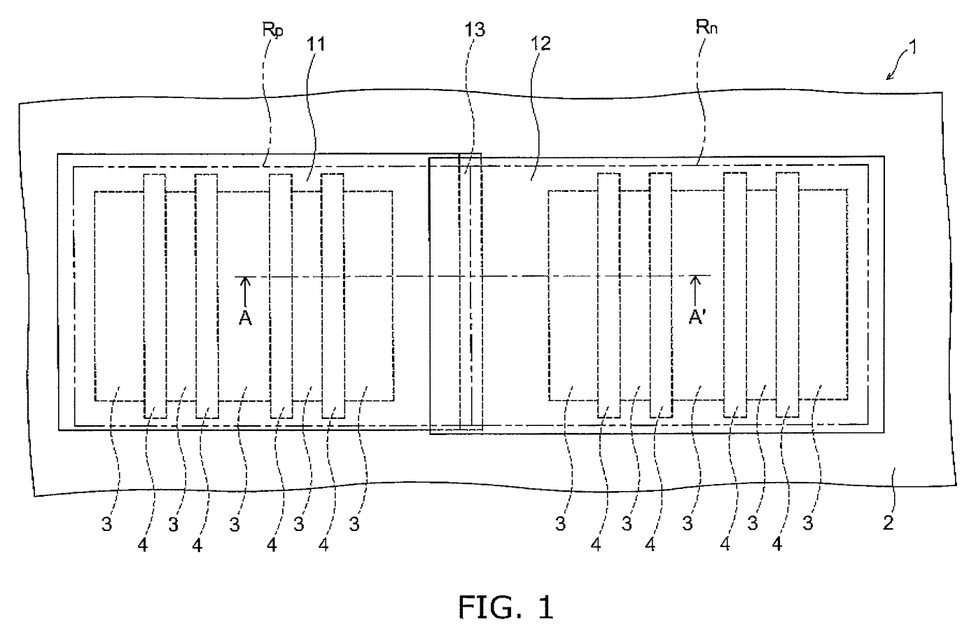

FIG. 1 is a plan view illustrating a semiconductor device according to this embodiment.

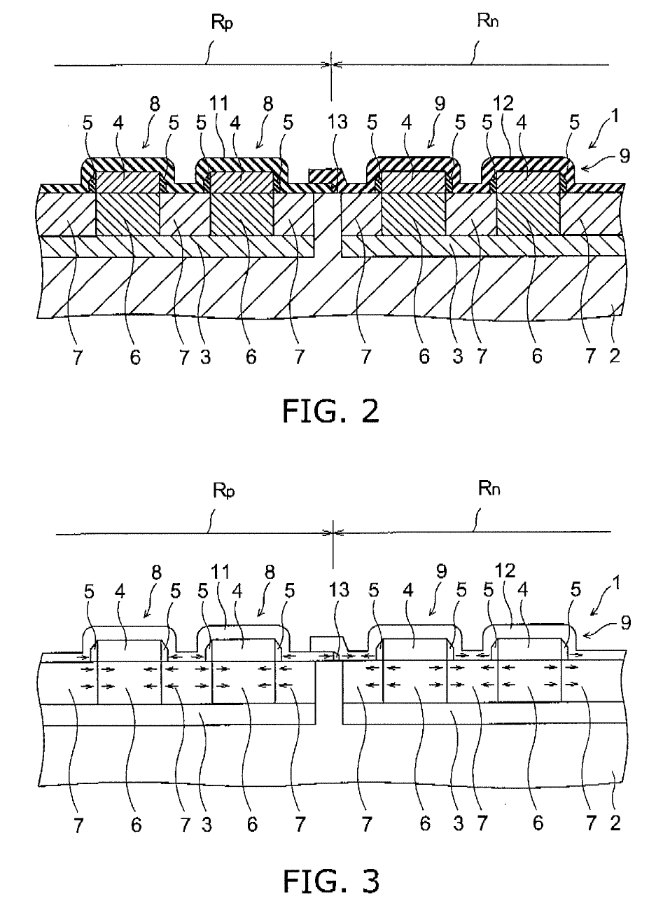

FIG. 2 is a cross-sectional view taken along line A-A′ shown in FIG. 1. In FIG. 2, characteristic portions in this embodiment are emphasized, and the ratio of dimensions in various portions does not necessarily correspond to that in FIG. 1.

As shown in FIGS. 1 and 2, the semiconductor device 1 according to this embodiment includes a silicon substrate 2 illustratively made of single crystal silicon, and a gate oxide film (not shown) is formed on the silicon substrate 2. In the silicon substrate 2, a pMOS region Rp and an nMOS region Rn are defined adjacent to each other. The pMOS region Rp and the nMOS region Rn each include an activated region 3 doped with impurities in the silicon substrate 2. As viewed in the direction perpendicular to the upper surface of the silicon substrate 2 (hereinafter referred to as “in plan view”), the activated region 3 has a rectangular shape.

On the silicon substrate 2, the pMOS region Rp and the nMOS region Rn are each provided with a plurality of gate electrodes 4 astride the activated region 3. The gate electrodes 4 have a striped shape and are arranged parallel to each other along the direction from the pMOS region Rp to the nMOS region Rn. That is, each gate electrode 4 extends in the direction parallel to the upper surface of the silicon substrate 2, the direction being orthogonal to the direction from the pMOS region Rp to the nMOS region Rn. The gate electrode 4 is illustratively made of polysilicon and has a height of e.g. 100 nm (nanometers). Furthermore, a sidewall 5 is provided over both the side surfaces of the gate electrode 4. The sidewall 5 is illustratively made of silicon oxide. For clarity of the drawing, the sidewall 5 is not shown in FIG. 1.

A channel region 6 is formed in the activated region 3 directly below the gate electrode 4. The region of the activated region 3 other than the directly underlying region of the gate electrode 4 is a source/drain region 7. Thus, a plurality of p-channel field effect transistors (pMOS) 8 are formed in the pMOS region Rp. Likewise, a plurality of n-channel field effect transistors (nMOS) 9 are formed in the nMOS region Rn.

Furthermore, on the silicon substrate 2, a compressive stress film 11 is provided over the pMOS region Rp of the silicon substrate 2. The compressive stress film 11 covers the gate electrode 4 and the sidewall 5 of each pMOS 8. In the compressive stress film 11, a compressive stress is generated inside by being constrained by the silicon substrate 2. The compressive stress film 11 itself tends to expand against the constraint.

On the other hand, a tensile stress film 12 is provided over the nMOS region Rn of the silicon substrate 2. The tensile stress film 12 covers the gate electrode 4 and the sidewall 5 of each nMOS 9. In the tensile stress film 12, a tensile stress is generated inside by being constrained by the silicon substrate 2. The tensile stress film 12 itself tends to shrink against the constraint.

In the vicinity of the boundary between the pMOS region Rp and the nMOS region Rn, the end portion of the compressive stress film 11 and the end portion of the tensile stress film 12 overlap each other. Specifically, the end portion of the tensile stress film 12 on the PMOS region Rp side extends on the end portion of the compressive stress film 11 on the nMOS region Rn side. The thickness of the compressive stress film 11 and the tensile stress film 12 is illustratively 60 nm. The compressive stress film 11 and the tensile stress film 12 are illustratively a silicon nitride film formed by plasma CVD (chemical vapor deposition). It is possible to control the composition ratio of the silicon nitride film, for example, by controlling the film formation condition in plasma CVD. Thus, the direction and magnitude of the internal stress of the film can be adjusted.

A buffer film 13 is provided on the lateral side of the end portion of the compressive stress film 11 on the nMOS region Rn side, that is, on the end side surface thereof. Hence, the buffer film 13 is located at or near the boundary between the pMOS region Rp and the nMOS region Rn, and located between the pMOS 8 and the nMOS 9. The buffer film 13 is in contact with the end surface of the compressive stress film 11 and covered with the tensile stress film 12. That is, the end portion of the tensile stress film 12 on the compressive stress film 11 side covers the buffer film 13 and the end portion of the compressive stress film 11 on the tensile stress film 12 side.

The buffer film 13 is illustratively formed from a soft inorganic material and has a smaller internal stress than the compressive stress film 11 and the tensile stress film 12. For example, the internal stress of the compressive stress film 11 is a compressive stress having a magnitude of 3.3 GPa (gigapascals), and the internal stress of the tensile stress film 12 is a tensile stress having a magnitude of 1.7 GPa. In this case, the internal stress of the buffer film 13 is a compressive stress or tensile stress having a magnitude less than 1.7 GPa, and illustratively a tensile stress having a magnitude less than 0.8 GPa. The buffer film 13 is illustratively a silicon oxide film formed by CVD using TEOS (tetraethyl orthosilicate, Si(OC₂HS)₄) as a raw material, or a film made of NSG (non-silicate glass). Furthermore, an interlayer insulating film (not shown) and the like are provided above the compressive stress film 11, the tensile stress film 12, and the buffer film 13, and a contact (not shown) is formed thereon.

Next, the operation of the semiconductor device according to this embodiment configured as above is described.

FIG. 3 is a cross-sectional view illustrating the operation of the semiconductor device according to this embodiment.

As shown in FIG. 3, in the semiconductor device 1, the compressive stress film 11 formed between the gate electrodes 4 in the pMOS region Rp tends to expand itself by its internal stress (compressive stress), and thereby applies a force to the silicon substrate 2 in such a direction that the adjacent gate electrodes 4 separate from each other. This results in pushing outward the region between the gate electrodes 4 in the silicon substrate 2, and accordingly compressing the channel region 6 formed directly below the gate electrode 4. Consequently, the lattice spacing of silicon in the channel region 6 becomes smaller than the original lattice constant. Thus, the driving performance of the pMOS 8 is enhanced. Here, the electrode length of the gate electrode 4 is sufficiently smaller than the length of the region between the gate electrodes 4. Hence, the effect of the compressive stress film 11 formed on the gate electrode 4 is negligible.

On the other hand, the tensile stress film 12 formed between the gate electrodes 4 in the nMOS region Rn tends to shrink itself by its internal stress (tensile stress), and thereby applies a force to the silicon substrate 2 in such a direction that the adjacent gate electrodes 4 come close to each other. This results in shrinking the region between the gate electrodes 4 in the silicon substrate 2, and accordingly expanding the channel region 6 formed directly below the gate electrode 4. Consequently, the lattice spacing of silicon in the channel region 6 becomes larger than the original lattice constant. Thus, the driving performance of the nMOS 9 is enhanced.

Here, in the semiconductor device 1, a buffer film 13 is provided between the compressive stress film 11 and the tensile stress film 12. Hence, no substantial force is applied to the portion of the silicon substrate 2 located directly below the buffer film 13. Thus, the stress field formed in the silicon substrate 2 by the compressive stress film 11 is prevented from reaching the nMOS region Rn and alleviating the stress field formed in the nMOS region Rn. Likewise, the stress field formed in the silicon substrate 2 by the tensile stress film 12 is prevented from reaching the pMOS region Rp and alleviating the stress field formed in the pMOS region Rp. This can prevent the decrease in driving performance of the transistor formed in the vicinity of the boundary between the pMOS region Rp and the nMOS region Rn. Furthermore, the distance between the pMOS region Rp and the nMOS region Rn can be reduced, and the semiconductor device 1 can be downsized.

In contrast, if the buffer film 13 is not provided, the stress field induced by the compressive stress film 11 extends into the nMOS region Rn, and the stress field induced by the tensile stress film 12 extends into the pMOS region Rp, alleviating the stress of each other. This results in decreasing the driving performance of the transistor formed in the vicinity of the boundary between the pMOS region Rp and the nMOS region Rn.

Next, a method for manufacturing a semiconductor device according to this embodiment is described.

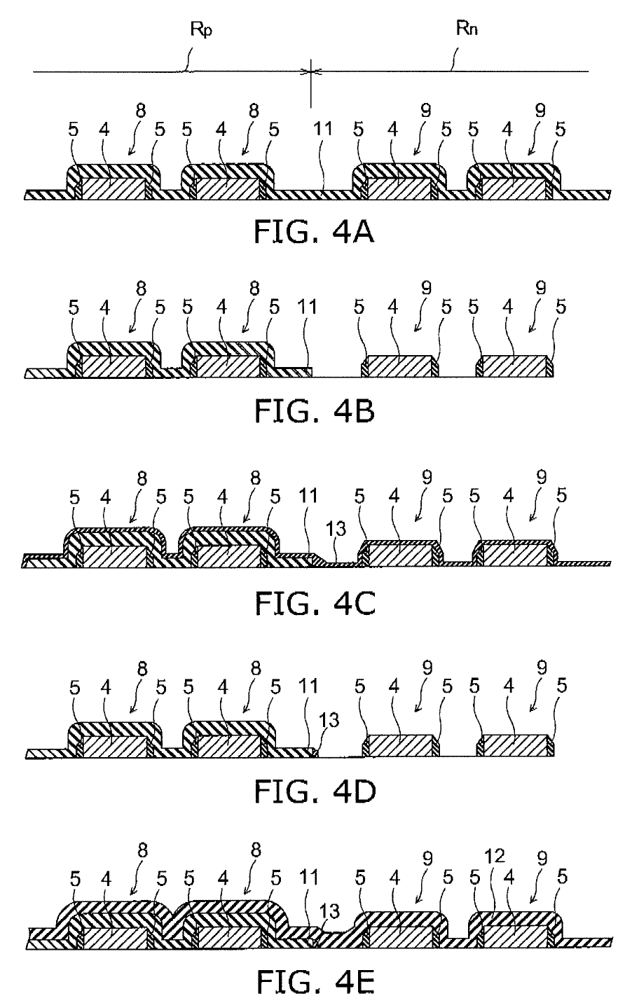

FIGS. 4A to 4E are process cross-sectional views illustrating the method for manufacturing a semiconductor device according to this embodiment. Although FIGS. 4A to 4E show the same cross section as FIG. 2, the silicon substrate 2 (see FIG. 2) is not shown for convenience.

First, as shown in FIG. 4A, by conventional methods, a gate oxide film, a gate electrode 4, a sidewall 5, a channel region 6 (see FIG. 2), and a source/drain region 7 (see FIG. 2) are formed on and in a silicon substrate 2 (see FIG. 2) to form a plurality of pMOS 8 in the pMOS region Rp and a plurality of nMOS 9 in the nMOS region.

Next, a compressive stress film 11 is formed entirely on the silicon substrate 2 to cover the gate electrode 4 and the sidewall 5 of each pMOS 8 and each nMOS 9. The compressive stress film 11 is a film with a compressive stress generated inside. The compressive stress film 11 is illustratively formed by depositing silicon nitride by plasma CVD.

Next, as shown in FIG. 4B, a photosensitive resist (not shown) is formed entirely, and then patterned so as to cover the pMOS region Rp and expose the nMOS region Rn. Then, this photosensitive resist is used as a mask to perform anisotropic etching. Thus, the compressive stress film 11 is removed from the nMOS region Rn and left on the pMOS region Rp.

Next, as shown in FIG. 4C, a buffer film 13 is formed entirely on the silicon substrate 2 to cover the compressive stress film 11. Here, the thickness of the buffer film 13 is not less than the thickness of the compressive stress film 11. The buffer film 13 is such a film that its internal stress has a smaller magnitude than the internal stress (compressive stress) of the compressive stress film 11. The buffer film 13 is illustratively formed by depositing silicon oxide by CVD using TEOS as a raw material.

Next, as shown in FIG. 4D, anisotropic etching is performed entirely. Thus, the buffer film 13 is etched back and left only on the end side surface of the compressive stress film 11. Here, it is also possible to perform this etching by combining anisotropic etching with isotropic etching. Thus, the shape of the residual portion of the buffer film 13 can be optimized.

Next, as shown in FIG. 4E, a tensile stress film 12 is formed entirely on the silicon substrate 2 to cover the compressive stress film 11 and the buffer film 13. The tensile stress film 12 is a film in which a tensile stress having a larger magnitude than the internal stress of the buffer film 13 is generated. The tensile stress film 12 is illustratively formed by depositing silicon nitride by plasma CVD.

Next, as shown in FIGS. 1 and 2, a photosensitive resist (not shown) is formed entirely, and then patterned so as to cover the nMOS region Rn, the end portion of the compressive stress film 11 on the nMOS region Rn side, and the buffer film 13, and expose the portion of the pMOS region Rp other than its end portion on the nMOS region Rn side. Then, this photosensitive resist is used as a mask to perform anisotropic etching on the tensile stress film 12. Thus, the tensile stress film 12 is removed from most of the pMOS region Rp and left on the nMOS region Rn, on the end portion of the compressive stress film 11 on the nMOS region Rn side, and on the buffer film 13. Here, it is also possible to perform the etching of the tensile stress film 12 by combining anisotropic etching with isotropic etching. Next, an interlayer insulating film (not shown) and the like are formed above the compressive stress film 11, the tensile stress film 12, and the buffer film 13, and a contact (not shown) is formed thereon. Thus, the semiconductor device 1 is manufactured.

Next, the effect of this embodiment is described.

According to this embodiment, the compressive stress film 11 compresses the channel region 6 of the pMOS 8, and the tensile stress film 12 expands the channel region 6 of the nMOS 9. Thus, the driving performance of these transistors can be enhanced. Furthermore, the buffer film 13 provided between the pMOS 8 and the nMOS 9 can prevent the situation in which the stress field induced by the compressive stress film 11 reaches the nMOS region Rn and the stress field induced by the tensile stress film 12 reaches the pMOS region Rp, alleviating the stress of each other. This serves to avoid decreasing the driving performance of the transistors located in the vicinity of the boundary between the pMOS region Rp and the nMOS region Rn. Consequently, all the transistors have a uniformly high level of driving performance, and hence the circuit stability is improved. Furthermore, in designing this semiconductor device, the design rule for the boundary between the pMOS region and the nMOS region can be alleviated. For example, the distance between the pMOS region and the nMOS region can be reduced.

Furthermore, according to this embodiment, no lithography process is required in forming the buffer film 13, but the buffer film 13 can be formed by the self-alignment process using the compressive stress film 11. Hence, even in manufacturing high-density semiconductor devices, there is no need to consider misalignment, and the buffer film 13 can be easily formed.

Moreover, according to this embodiment, the end portion of the tensile stress film 12 is caused to overlap the buffer film 13 and the end portion of the compressive stress film 11. Thus, a sufficient margin can be ensured in processing the compressive stress film 11 and the tensile stress film 12. Hence, the semiconductor device according to this embodiment is easy to manufacture.

Next, a first variation of the first embodiment is described.

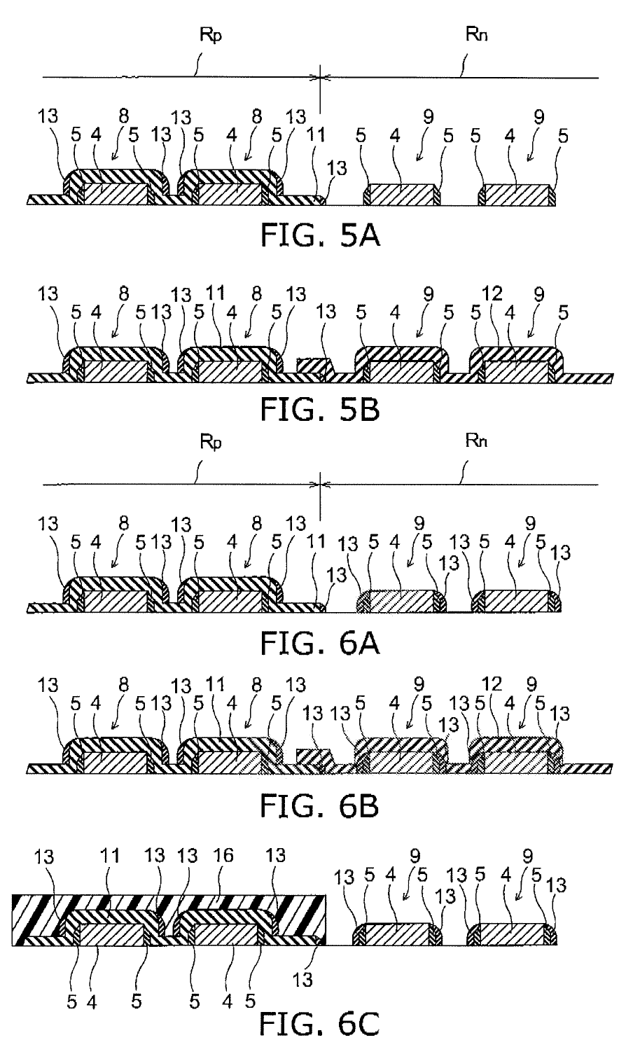

FIG. 5A is a process cross-sectional view illustrating a method for manufacturing a semiconductor device according to this variation, and FIG. 5B is a cross-sectional view illustrating this semiconductor device. Although FIGS. 5A and 5B show the same cross section as FIG. 2, the silicon substrate 2 (see FIG. 2) is not shown for convenience.

In the method for manufacturing a semiconductor device according to this variation, the process until the step of entirely forming a buffer film 13 is the same as that of the above first embodiment. More specifically, as shown in FIG. 4C, a pMOS 8 and an nMOS 9 are formed in the silicon substrate 2. A compressive stress film 11 is formed on the pMOS region Rp, and a buffer film 13 is formed entirely to cover the compressive stress film 11.

Next, like the above first embodiment, anisotropic etching is performed entirely to etch back the buffer film 13. At this time, as shown in FIG. 5A, besides remaining on the end side surface of the compressive stress film 11, the buffer film 13 may be left also near the directly overlying region of the sidewall 5 on the compressive stress film 11, that is, on the step portion resulting from the gate electrode 4 of the pMOS 8. In this case, as shown in FIG. 5B, the buffer film 13 left on this step portion is left also after completion of the semiconductor device. However, the buffer film 13 left on this step portion does not act on the silicon substrate 2, and hence does not affect the operation of the transistor. Thus, this variation can also achieve the same effect as the above first embodiment. The configuration, operation, and effect in this variation other than the foregoing are the same as those in the above first embodiment.

Next, a second variation of the first embodiment is described.

FIG. 6A is a process cross-sectional view illustrating a method for manufacturing a semiconductor device according to this variation, FIG. 6B is a cross-sectional view illustrating this semiconductor device, and FIG. 6C is a process cross-sectional view illustrating another method for manufacturing a semiconductor device according to this variation. Although FIGS. 6A to 6C show the same cross section as FIG. 2, the silicon substrate 2 (see FIG. 2) is not shown for convenience.

In the method for manufacturing a semiconductor device according to this variation, the process until the step of entirely forming a buffer film 13 is the same as that of the above first embodiment and the first variation thereof. More specifically, as shown in FIG. 4C, a buffer film 13 is formed entirely on the silicon substrate 2.

Next, like the above first embodiment and the first variation thereof, anisotropic etching is performed entirely to etch back the buffer film 13. At this time, as shown in FIG. 6A besides remaining on the end side surface of the compressive stress film 11 and the step portion resulting from the gate electrode 4 of the pMOS 8 on the compressive stress film 11, the buffer film 13 may be left also on the side surface of the sidewall 5 of the nMOS 9. In this case, as shown in FIG. 6B, the buffer film 13 is left also after completion of the semiconductor device. That is, the buffer film 13 is present also on the side surface of the gate electrode 4 covered with the tensile stress film 12.

The semiconductor device shown in FIG. 6B also includes a buffer film 13 in the vicinity of the boundary between the pMOS region Rp and the nMOS region Rn. Hence, the decrease in driving performance of the pMOS 8 and the nMOS 9 can be prevented. However, because the buffer film 13 is interposed between the tensile stress film 12 and the gate electrode 4 of the nMOS 9, the effect of expanding the channel region 6 of the nMOS 9 by the tensile stress film 12 may be slightly decreased. To resolve this problem, after the step shown in FIG. 6A, as shown in FIG. 6C, a photosensitive resist 16 to expose the nMOS region Rn can be formed by lithography and used as a mask to perform etching, thereby removing the buffer film 13 left on the side surface of the sidewall 5 of the nMOS 9. This etching is illustratively performed by combining anisotropic etching with isotropic etching. Thus, the final shape of the manufactured semiconductor device is as shown in FIG. 5B, and can achieve the same performance as the semiconductor device 1 according to the above first embodiment. The configuration, operation, and effect in this variation other than the foregoing are the same as those in the above first embodiment.

Next, a second embodiment of the invention is described.

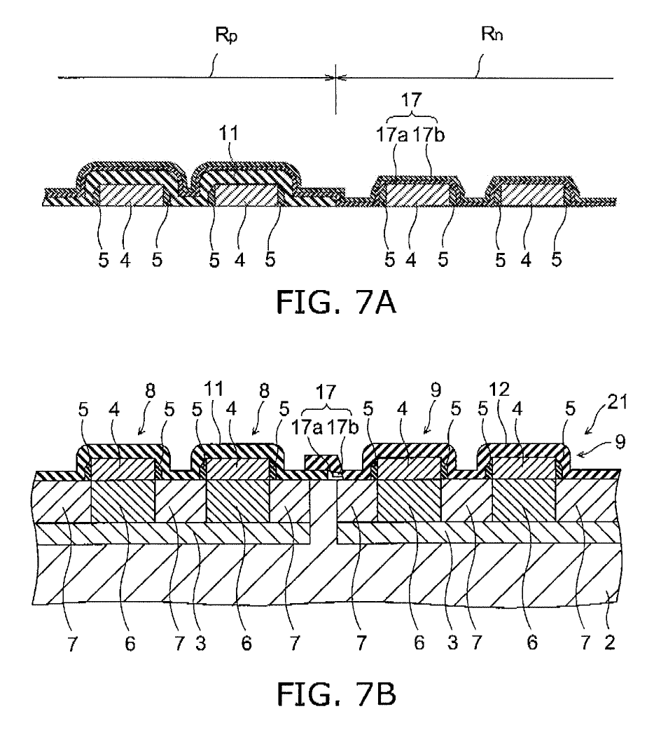

FIG. 7A is a process cross-sectional view illustrating a method for manufacturing a semiconductor device according to this embodiment, and FIG. 7B is a cross-sectional view illustrating the semiconductor device according to this embodiment.

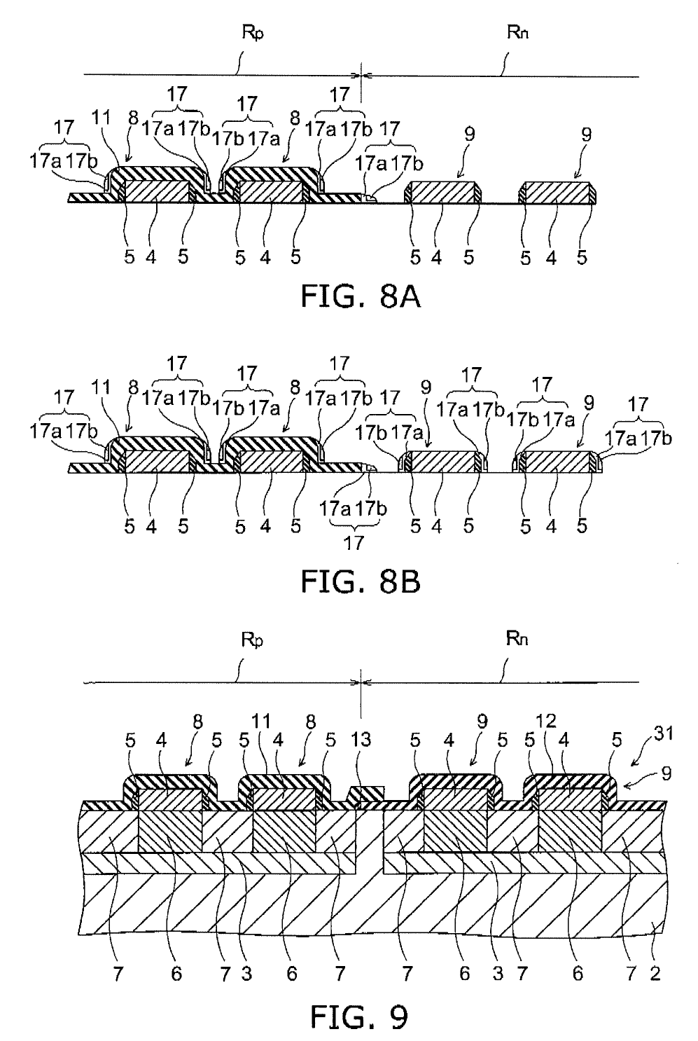

FIG. 8A is a process cross-sectional view illustrating another method for manufacturing a semiconductor device according to this embodiment, and FIG. 8B is a process cross-sectional view illustrating still another method for manufacturing a semiconductor device according to this embodiment.

Although FIGS. 7A, 7B, 8A, and 8B show the same cross section as FIG. 2, the silicon substrate 2 (see FIG. 7B) is not shown in FIGS. 7A, 8A, and 8B for convenience.

In this embodiment, the buffer film is a multilayer film having a two-layer structure. In the method for manufacturing a semiconductor device according to this embodiment, first, a compressive stress film 11 is formed on the pMOS region Rp by the process shown in FIGS. 4A and 4B.

Next, as shown in FIG. 7A, a two-layer buffer film 17 is formed entirely. For example, a silicon oxide (SiO₂) film is formed from TEOS as a lower layer 17a of the buffer film 17. Next, a silicon nitride (SiN) film is formed as an upper layer 17b. The subsequent process is the same as the process shown in FIGS. 4D and 4E in the above first embodiment.

Thus, as shown in FIG. 7B, in the semiconductor device 21 according to this embodiment, the buffer film 17 can be formed in a two-layer structure. Consequently, the shape of the buffer film 17 left on the end side surface of the compressive stress film 11 can be accurately controlled. It is noted that, depending on the condition for etching back the buffer film 17, as shown in FIG. 8A, the buffer film 17 may be left also on the step portion resulting from the gate electrode 4 of the pMOS 8 on the compressive stress film 11. Furthermore, as shown in FIG. 8B, the buffer film 17 may be left also on the side surface of the sidewall 5 of the nMOS 9. The configuration, operation, and effect in this embodiment other than the foregoing are the same as those in the above first embodiment. It is noted that the buffer film can also be a multilayer film made of three or more layers.

Next, a third embodiment of the invention is described.

FIG. 9 is a cross-sectional view illustrating a semiconductor device according to this embodiment.

As shown in FIG. 9, in the semiconductor device 31 according to this embodiment, in the vicinity of the boundary between the pMOS region Rp and the nMOS region Rn, the end portion of the compressive stress film 11 on the nMOS region Rn side covers the buffer film 13 and the end portion of the tensile stress film 12 on the pMOS region Rp side.

Such a structure can be realized by reversing the order of forming the compressive stress film 11 and the tensile stress film 12 with respect to the above first embodiment. More specifically, after a pMOS 8 and an nMOS 9 are formed in the silicon substrate 2, first, a tensile stress film 12 is formed over the nMOS region Rn. Next, a buffer film 13 is formed entirely, and by etch back, the buffer film 13 is left on the end side surface of the tensile stress film 12. Subsequently, a compressive stress film 11 is formed over the pMOS region Rp, the end portion of the tensile stress film 12, and the buffer film 13.

Also in this embodiment, like the above first embodiment, the alleviation of stress can be prevented by the buffer film 13. Furthermore, a sufficient margin for processing the tensile stress film 12 and the compressive stress film 11 can be ensured, and hence the processing is facilitated. The configuration, manufacturing method, operation, and effect in this embodiment other than the foregoing are the same as those in the above first embodiment.

The invention has been described with reference to the embodiments and the variations thereof. However, the invention is not limited to these embodiments and variations. Any suitable addition, deletion, and design change of components in the above embodiments and variations made by those skilled in the art are also encompassed within the scope of the invention as long as they fall within the spirit of the invention. For example, the material of the substrate is not limited to silicon, but other semiconductor materials can be also used. Furthermore, the above embodiments and variations can be practiced also in combination with each other. For example, in the above third embodiment, the buffer film can be a multilayer film as illustrated in the above second embodiment.

1. A semiconductor device comprising:
a semiconductor substrate;
a p-channel field effect transistor formed in a first region of the semiconductor substrate;
an n-channel field effect transistor formed in a second region of the semiconductor substrate;
a compressive stress film with a compressive stress generated inside, the compressive stress film covering the first region;
a tensile stress film with a tensile stress generated inside, the tensile stress film covering the second region; and
a buffer film located between the p-channel field effect transistor and the n-channel field effect transistor on the semiconductor substrate, the magnitude of internal stress of the buffer film being smaller than the magnitude of the compressive stress of the compressive stress film and the magnitude of the tensile stress of the tensile stress film.

2. The device according to claim 1, wherein the buffer film is provided on an end side surface of one film of the compressive stress film and the tensile stress film on the other film side, and an end portion of the other film of the compressive stress film and the tensile stress film covers the buffer film and an end portion of the one film on the other film side.

3. The device according to claim 1, wherein the buffer film is present also on a step portion resulting from a gate electrode on the one film.

4. The device according to claim 1, wherein the buffer film is present also on a side surface of a gate electrode covered with the other film.

5. The device according to claim 1, wherein the buffer film is formed from silicon oxide.

6. The device according to claim 1, wherein the buffer film is formed from non-silicate glass.

7. The device according to claim 1, wherein the compressive stress film is formed from silicon nitride.

8. The device according to claim 1, wherein the tensile stress film is formed from silicon nitride.

9. The device according to claim 1, wherein the buffer film is a multilayer film in which a plurality of layers are laminated.

10. The device according to claim 9, wherein the buffer film includes:
a lower layer made of silicon oxide; and
an upper layer made of silicon nitride.

11. A method for manufacturing a semiconductor device, comprising:
forming a p-channel field effect transistor in a first region of a semiconductor substrate and forming an n-channel field effect transistor in a second region of the semiconductor substrate;
forming a compressive stress film with a compressive stress generated inside so that the compressive stress film covers the first region;
forming a buffer film entirely, the magnitude of internal stress of the buffer film being smaller than the magnitude of the compressive stress of the compressive stress film;
etching the buffer film so that the buffer film is left at least on an end side surface of the compressive stress film on the second region side;
entirely forming a tensile stress film with a tensile stress generated inside, the magnitude of the tensile stress being larger than the magnitude of the internal stress of the buffer film; and
selectively removing the tensile stress film so that the tensile stress film is left on the second region, on an end portion of the compressive stress film on the second region side, and on the buffer film.

12. The method according to claim 11, wherein said forming a buffer film includes depositing silicon oxide by CVD using TEOS as a raw material.

13. The method according to claim 11, wherein said forming a buffer film includes:
forming a lower layer made of silicon oxide; and
forming an upper layer made of silicon nitride.

14. The method according to claim 11, wherein said etching of the buffer film is anisotropic etching.

15. The method according to claim 11, further comprising, after said etching the buffer film:
etching the second region to remove the buffer film left on the second region.

16. A method for manufacturing a semiconductor device, comprising:
forming a p-channel field effect transistor in a first region of a semiconductor substrate and forming an n-channel field effect transistor in a second region of the semiconductor substrate;
forming a tensile stress film with a tensile stress generated inside so that the tensile stress film covers the second region;
forming a buffer film entirely, the magnitude of internal stress of the buffer film being smaller than the magnitude of the tensile stress of the tensile stress film;
etching the buffer film so that the buffer film is left at least on an end side surface of the tensile stress film on the first region side;
entirely forming a compressive stress film with a compressive stress generated inside, the magnitude of the compressive stress being larger than the magnitude of the internal stress of the buffer film; and
selectively removing the compressive stress film so that the compressive stress film is left on the first region, on an end portion of the tensile stress film on the first region side, and on the buffer film.

17. The method according to claim 16, wherein said forming a buffer film includes depositing silicon oxide by CVD using TEOS as a raw material.

18. The method according to claim 16, wherein said forming a buffer film includes:
forming a lower layer made of silicon oxide; and
forming an upper layer made of silicon nitride.

19. The method according to claim 16, wherein said etching of the buffer film is anisotropic etching.

20. The method according to claim 16, further comprising, after said etching the buffer film:
etching the first region to remove the buffer film left on the first region.
